(19) United States
(12) Patent Application Publication
(10) Pub. No.: US 2024/0107803 A1
(43) Pub. Date: Mar. 28, 2024

(54) DISPLAY APPARATUS

(71) Applicant: LG Display Co., Ltd., Seoul (KR)

(72) Inventor: Young-Kwun KIM, Paju-si (KR)

(21) Appl. No.: 18/471,207

(22) Filed: Sep. 20, 2023

(30) Foreign Application Priority Data
Sep. 22, 2022 (KR) 10-2022-0119793

(51) Int. Cl. H10K 59/12; H10K 59/19; H10K 59/40; H10K 59/80; H10K 77/10

(52) U.S. Cl. CPC H10K 59/1201; H10K 59/19; H10K 59/40; H10K 59/8051; H10K 59/8052; H10K 59/873; H10K 77/111; H10K 2102/302

(57) ABSTRACT

A display apparatus according to an embodiment of the present disclosure comprises a display area, a first area disposed in the display area and comprising a hole region and a first pattern portion surrounding the hold region, a plurality of first patterns disposed in the first pattern portion, and a first insulating layer and a second insulating layer disposed on the plurality of first patterns, wherein the first insulating layer and the second insulating layer are spaced apart from each other between the plurality of first patterns, and wherein the first insulating layer and the second insulating layer are in contact with each other on an upper surface of each of the plurality of first patterns.

### CROSS-REFERENCE TO RELATED APPLICATION

The present application claims the priority of Korean Patent Application No. 10-2022-0119793 filed on Sep. 22, 2022, which is hereby incorporated by reference in its entirety.

### BACKGROUND

### Technical Field

The present disclosure relates to a display apparatus, and more particularly, to a display apparatus capable of preventing perpetration of external moisture.

### Description of the Related Art

Various sizes, various shapes, and various functions are included for recent display apparatuses capable of displaying various types of information and interacting with users who watch the corresponding information.

Such display apparatuses include liquid crystal display (LCD) devices, electrophoretic display (EPD) devices, and organic light emitting diode (OLED) display devices.

The organic light emitting diode display device is a self-luminous display device and does not need a separate light source differently from the liquid crystal display device, so that it can be manufactured to be lightweight and thin. In addition, the organic light emitting diode display device is not only advantageous in terms of power consumption due to low voltage driving, but also has excellent color implementation, response speed, viewing angle, and contrast ratio (CR), and is being studied as a next-generation display.

The organic light emitting diode display device displays an image by controlling a current flowing through an organic light emitting diode using a plurality of thin film transistors (TFTs).

A display apparatus has been developed by adding a camera, a speaker, a sensor, and the like.

Particularly, a hole-in-display structure in which a hole is formed in the apparatus has been applied in order to place a sensor such as a camera on the display apparatus.

### BRIEF SUMMARY

The inventors have realized that, due to forming a hole in the display apparatus, there is a problem in that external moisture penetrates into a display area inside a display panel.

In the present disclosure, a through hole may be formed in a region for disposing a camera in a display area of a display apparatus.

The through hole may be formed by removing a substrate and layers on the substrate.

To form the through hole in the display area, a first area including a hole region, a first pattern portion, a first dam portion, and a second pattern portion may be disposed.

In order to disconnect a light emitting layer, a plurality of first patterns may be disposed in the first pattern portion, which is adjacent to the hole region of the first area, and each of the plurality of first patterns may include a lower pattern having a columnar shape and an upper pattern having a trapezoidal shape on the lower pattern.

An insulation layer disposed on the plurality of first patterns may not be filled in a reverse taper region formed between the plurality of first patterns to thereby form an empty space ES.

A seam may be formed due to the empty space ES and an end of the upper pattern having the trapezoidal shape.

In the hole region formed by removing the substrate and the layers on the substrate, side surfaces of the layers on the substrate may be exposed to the outside.

External moisture introduced into an organic insulating layer formed of an organic material among the layers on the substrate and exposed to the outside may penetrate into the display area of a display panel through the seam formed in the first pattern portion adjacent to the hole region, and thus there was a problem of reducing the quality of the display apparatus.

Accordingly, in the present disclosure, a display apparatus can prevent penetration of external moisture by improving a stacked structure of an insulation layer and a protective layer in the first pattern portion of the first area formed for disposing a camera of a hole-in-display.

A problem to be solved according to an embodiment of the present disclosure is to provide a display apparatus capable of preventing penetration of external moisture by disposing a protective layer between insulation layers on a first pattern portion of a first area formed for disposing a camera.

The problems to be solved according to embodiments of the present disclosure are not limited to the above-mentioned problems, and other problems not mentioned above will be clearly understood by those skilled in the art from the description below.

The features and aspects of the present disclosure are not limited to those described above. Additional features and advantages of the disclosure will be set forth in the description which follows, and in part will be apparent to those skilled in the art from the description or may be learned by practice of the disclosure. These and other advantages of the disclosure may be realized and attained by the structure particularly pointed out in, or derivable from, the written description, claims hereof, and the appended drawings.

To achieve these and other advantages of the present disclosure and in accordance with the purpose of the disclosure, as embodied and broadly described herein, a display apparatus according to an embodiment of the present disclosure comprises a display area, a first area disposed in the display area and comprising a hole region and a first pattern portion adjacent the hole region, a plurality of first patterns disposed in the first pattern portion, and a first insulating layer and a second insulating layer disposed on the plurality of first patterns, wherein the first insulating layer and the second insulating layer are spaced apart from each other between the plurality of first patterns, and wherein the first insulating layer and the second insulating layer are in contact with each other on an upper surface of each of the plurality of first patterns.

In another aspect, a display apparatus according to another embodiment of the present disclosure comprises a display area, a first area and a plurality of pixels disposed in the display area, an anode electrode, a light emitting layer, and a cathode electrode disposed in each of the plurality of pixels, an encapsulation layer disposed on the cathode electrode, a first insulating layer disposed on the encapsulation layer, a first touch electrode disposed on the first insulating layer, a second insulating layer disposed on the first touch electrode, and a second touch electrode disposed on the second insulating layer, wherein the first area comprises a first pattern portion, a second pattern portion and a first dam portion between the first pattern portion and the second pattern portion, wherein the first insulating layer and the second insulating layer extend in the first pattern portion, the first dam portion, and the second pattern portion.

Other embodiment specifics are included in the detailed description and drawings.

The display apparatus according to the example embodiments of the present disclosure may effectively prevent penetration of external moisture into the display area of a panel by providing the insulating layer and the protective layer in the first pattern portion of the first area that is formed to dispose a camera, and it is possible to provide a display apparatus and a manufacturing method of the same capable of preventing the panel quality from deteriorating due to the moisture permeation.

Effects of the present disclosure are not limited to the effects mentioned above, and other effects not mentioned will be clearly understood by those skilled in the art from the description below.

Since the content of the disclosure described in the problem to be solved, the means for solving the problem and the effect does not specify the essential features of the claims, the scope of the claims is not limited by the matters described in the content of the disclosure.

It is to be understood that both the foregoing general description and the following detailed description are explanatory and by way of examples and are intended to provide further explanation of the disclosure as claimed without limiting its scope.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a plan view illustrating a display apparatus according to an example embodiment of the present disclosure;

FIG. 2 is a three-dimensional view illustrating a display apparatus according to an example embodiment of the present disclosure;

FIG. 3 is a three-dimensional view illustrating a display apparatus according to an example embodiment of the present disclosure;

FIG. 4 is an enlarged view illustrating a first area PH of FIG. 1;

FIG. 5 is a cross-sectional view showing an example of a cross-section taken along line A-A′ of FIG. 1;

FIG. 6 is a cross-sectional view showing an example of a cross-section taken along line B-B′ of FIG. 1; and

FIG. 7 is an enlarged view illustrating a first pattern portion PT1 of FIG. 6.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “consisting of,” and the like mentioned in this disclosure are used, other parts can be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is not used, one or more other parts can be located between the two parts.

In describing a temporal relationship, for example, when a temporal predecessor relationship is described as being “after,” “subsequent,” “next to,” “prior to,” or the like, unless “immediately” or “directly” is not used, cases that are not continuous can also be included

Although the terms first, second, and the like are used to describe various components, these components are not substantially limited by these terms. These terms are used only to distinguish one component from another component. Therefore, a first component described below can substantially be a second component within the technical spirit of the present disclosure.

In describing components of the present disclosure, terms such as first, second, A, B, (a), (b) and the like can be used. These terms are only for distinguishing the components from other components, and an essence, order, order, or number of the components is not limited by the terms. Further, when it is described that a component is “connected,” “coupled” or “contact” to another component, the component can be directly connected or contact the another component, but it should be understood that other component can be “interposed” between the components or the components can be “connected,” “coupled,” or “contact” through one or more other components.

The term “at least one” should be understood to include all possible combinations from one or more related items. For example, the meaning of “at least one of the first, second, and third items” means 2 of the first, second, and third items as well as each of the first, second, or third items. It can mean a combination of all items that can be presented from more than one.

As used herein, the term “apparatus” or “device” can include a display apparatus such as a liquid crystal module (LCM) including a display panel and a driving unit or circuit for driving the display panel, and an organic light emitting display module (OLED module). Further, the term “apparatus” can further include a notebook computer, a television, a computer monitor, a vehicle electric apparatus including an apparatus for a vehicle or other type of vehicle, and a set electronic apparatus or a set apparatus such as a mobile electronic apparatus of a smartphone or an electronic pad, etc., which are a finished product (complete product or final product) including LCM and OLED module.

Accordingly, the apparatus or device in the present specification can include the display apparatus itself such as the LCM, the OLED module, etc., and the application product including the LCM, the OLED module, or the like, or the set apparatus, which is the apparatus for end users.

In addition, in some embodiments, the LCM or the OLED module composed of a display panel and a driving unit can be expressed as a “display apparatus,” and an electronic apparatus as a finished product including the LCM and the OLED module can be distinguished and expressed as a “set apparatus.” For example, the display apparatus can include the liquid crystal (LCD) or the organic light emitting (OLED) display panel, and a source PCB that is a control unit or controller for driving the display panel. The set apparatus can further include a set PCB, which is a set controller electrically connected to the source PCB to drive the entire set apparatus.

All types of display panels such as the liquid crystal display panel, the organic light emitting display panel, and the electroluminescent display panel can be used for the display panel used in the embodiments of the present specification, but not limited thereto. For example, the display panel can be the display panel capable of generating sound by being vibrated by the vibrating device according to the example embodiment of the present specification. The display panel applied to the display apparatus according to the embodiment of the present specification is not limited to the shape or size of the display panel. Further, all the components of each display apparatus according to all embodiments of the present disclosure are operatively coupled and configured.

Each feature of the various embodiments of the present specification can be partially or wholly combined or combined with each other, technically various interlocking and driving are possible, and each of the embodiments can be independently implemented with respect to each other or can be implemented together in a related relationship.

Hereinafter, embodiments of the present specification will be described with reference to the accompanying drawings and examples. The scales of the components shown in the drawings have different scales from the actual ones for convenience of explanation, and thus are not limited to the scales shown in the drawings.

Reference will now be made in detail to embodiments of the present disclosure, examples of which are illustrated in the accompanying drawings.

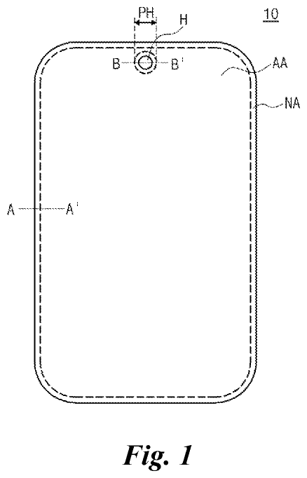

FIG. 1 is a plan view schematically illustrating an example of a display apparatus according to an embodiment of the present disclosure.

The display apparatus 10 may include a plurality of areas. For example, the display apparatus 10 may include at least one display area AA in which an image is displayed, and a pixel array including pixels may be formed in the display area AA. The display apparatus 10 may further include at least one non-display area NA in which an image is not displayed and a driving circuit portion and a dam portion are provided, and the non-display area NA may be provided on a side of the display area AA. For example, the non-display area NA may be adjacent to one or more side surfaces of the display area AA.

Referring to FIG. 1, the non-display area NA may surround the display area AA having a substantially rectangular shape and may be disposed outside the display area AA. However, it should be understood that the shapes of the display area AA and the arrangement of the non-display area NA adjacent to the display area AA are not specifically limited to the example display apparatus 10 shown in FIG. 1. The display area AA and the non-display area NA may have shapes corresponding to arbitrary shapes of the display apparatus 10. Examples of these shapes may include a pentagon, a hexagon, a circle, an ellipse, and the like, but embodiments of the present disclosure are not limited thereto.

Each of the pixels of the display area AA may include sub-pixels, and the sub-pixels may display red (R), green (G), blue (B), and white (W) colors. In addition, the pixels and the sub-pixels may be associated with pixel circuits including one or more thin film transistors (TFTs) formed on a substrate of the display apparatus 10, respectively. Each of the pixel circuits may be electrically connected to a gate line and a data line in order to communicate with one or more driving circuits, for example, a gate driver GIP and a data driver D-IC disposed in the non-display area NA of the display apparatus 10.

One or more driving circuits may be implemented as TFTs configured in the non-display area NA shown in FIG. 1. For example, the gate driver GIP may be implemented using a plurality of TFTs on the substrate of the display apparatus 10. Non-limiting examples of circuits that can be implemented with the TFTs on the substrate may include an inverter circuit, a multiplexer, an electro static discharge (ESD) circuit, and the like, but the embodiments of the present disclosure are not limited thereto.

Some driving circuits may be provided as integrated circuit (IC) chips and may be mounted in the non-display area NA of the display apparatus 10 using a chip-on-glass (COG) or other similar method. In addition, some driving circuits may be mounted on another substrate and may be coupled to connection interfaces (pads/bumps and pins) disposed in the non-display area NA using a printed circuit such as a flexible printed circuit board (FPCB), a chip-on-film (COF), a tape-carrier-package (TCP) or other suitable technologies.

In the embodiments of the present disclosure, at least two different types of TFTs may be used in a TFT substrate for display. The types of TFTs applied to a part of the pixel circuit and a part of the driving circuit may vary according to type or configuration of the display.

For example, the pixel circuit may be implemented with a TFT having an oxide active layer, which may be referred to as an oxide TFT, and the driving circuit may be implemented with an oxide TFT and a TFT having a low-temperature polycrystalline silicon active layer, which may be referred to as an LTPS TFT. Unlike LTPS TFTs, oxide TFTs do not suffer from a variation problem of a threshold voltage Vth from the pixel-to-pixel. A uniform threshold voltage Vth can also be obtained in an array of pixel circuits for display. The uniformity problem of the threshold voltage Vth between the TFTs implementing the driving circuit will have less direct influence on the luminance uniformity of the pixels.

By embedding gate drive ICs inside the display panel, the driving circuits (e.g., GIP) can provide cost reduction due to a decrease in the number of drive ICs and high-speed scan signals.

By using the driving circuits on a substrate to be implemented with LTPS TFTs, signals and data can be provided to the pixels at a higher clock than in the case where all the TFTs in the TFT panel are formed of oxide TFTs. Accordingly, a display capable of high-speed operation can be provided without spots such as mura or the like. For example, advantages of the oxide TFT and the LTPS TFT can be combined with a design of the TFT panel, so that the oxide TFT and the LTPS TFT can be selected and used according to the respective advantages.

The display area AA may include a first area PH. The first area PH may include a hole region H for disposing a camera and a first pattern portion PT1, a first dam portion DM, a second pattern portion PT2, and a routing wiring region RK surrounding the hole region H, and these configurations will be described in detail later.

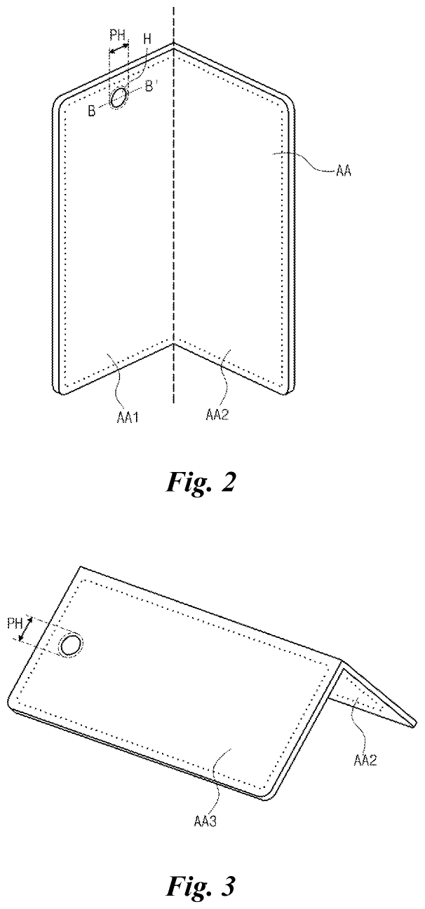

FIG. 2 and FIG. 3 are three-dimensional views schematically illustrating an example of a display apparatus according to an example embodiment of the present disclosure.

The display apparatus according to the example embodiment of the present disclosure may be applied to a foldable display device.

The foldable display device may include at least one display area AA.

In the foldable display device, one display area of the display device may be folded along a folding line to be divided into a first display area AA1 and a second display area AA2. Alternatively, the foldable display device may have a plurality of display areas on the inside and outside of the display device. Pixels may be formed in the display area.

Referring to FIG. 3, the foldable display device may include a first display area AA1 and a second display area AA2 disposed inside the display device and may further include a third display area AA3 disposed outside of the display device.

Referring to FIG. 2 and FIG. 3, one or more first areas PH for arranging a camera may be provided in the first display area AA1 and the second display area AA2 disposed inside the display device or in the third display area AA3 disposed outside the display device.

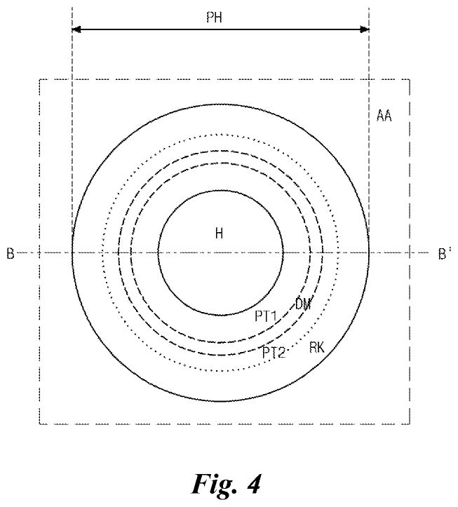

FIG. 4 is an enlarged view schematically illustrating the first area PH of the display apparatus 10 of the present disclosure.

The first area PH may include a hole region H for disposing a camera, a first pattern portion PT1 surrounding the hole region H, a first dam portion DM surrounding the first pattern portion PT1, a second pattern portion PT2 surrounding the first dam portion DM, and a routing wiring region RK surrounding the second pattern portion PT2.

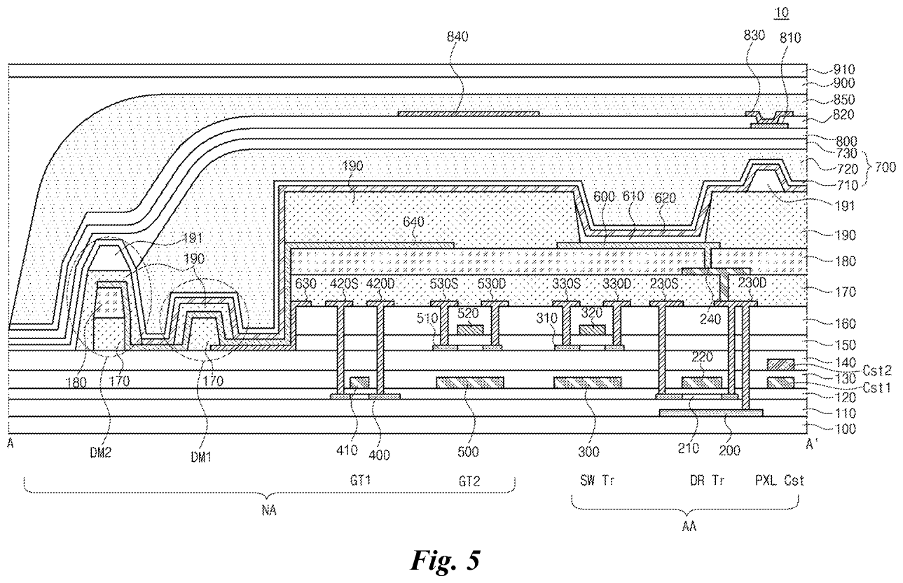

FIG. 5 is a cross-sectional view schematically illustrating an example of a cross-section taken along line A-A′ of FIG. 1.

Referring to FIG. 5, a substrate 100 of the display apparatus according to the example embodiment of the present disclosure may include a first substrate, a second substrate, and an intermediate layer between the first substrate and the second substrate.

The first substrate and the second substrate may be formed of at least one of polyimide, polyethersulfone, polyethylene terephthalate, and polycarbonate, and the embodiments of the present disclosure are not limited thereto. When the substrate is formed of a plastic material, the manufacturing process of the display apparatus may be performed while a support substrate made of glass is disposed under the substrate, and the support substrate may be released after the manufacturing process of the display apparatus is completed. In addition, after releasing the support substrate, a back plate for supporting the substrate may be disposed under the substrate. When the substrate is formed of a plastic material, moisture may permeate the substrate and progress to the thin film transistor or light emitting element layer, which may deteriorate the performance of the display apparatus. To prevent deterioration in performance of the display apparatus due to moisture permeation, the display apparatus according to the example embodiment of the present disclosure may include two substrates of a first substrate and a second substrate made of a plastic material. Further, by forming an intermediate layer between the first substrate and the second substrate, it is possible to prevent moisture from penetrating the substrate, thereby improving performance of the product. The intermediate layer may be an inorganic layer. For example, the intermediate layer may be a single layer or multiple layers of silicon nitride (SiNx) or silicon oxide (SiOx), but is not limited thereto.

The display apparatus may include a plurality of areas on the substrate 100. In the present disclosure, the display area AA and the non-display area NA are provided on the substrate 100, but are not limited thereto.

A buffer layer made of a single layer or multiple layers of silicon nitride (SiNx) or silicon oxide (SiOx) may be disposed in the display area AA and the non-display area NA on the substrate 100. The buffer layer may serve to improve adhesion between the layers formed on the buffer layer and the substrate 100 and to block various types of defect factors such as alkali components flowing out from the substrate 100. In addition, the buffer layer may delay diffusion of moisture or oxygen penetrating into the substrate 100.

The buffer layer may be omitted based on the type and material of the substrate, the structure and type of the thin film transistor, and the like.

In the display area AA and the non-display area NA, transistors may be formed on the substrate 100 and the buffer layer. The transistors in the display area AA may include a switching transistor SW Tr and a driving transistor DR Tr for driving the sub-pixels, and the transistors in the non-display area NA may include a first gate driving transistor GT1 and a second gate driving transistor GT2 for driving the gate driver GIP.

A light blocking layer 200 may be disposed under the driving transistor DR Tr and on the substrate 100 or the buffer layer. Accordingly, the light blocking layer 200 may be disposed between the driving transistor DR Tr and the substrate 100 or the buffer layer.

The light blocking layer 200 may block light directed to a first semiconductor layer 210 of the driving transistor DR Tr and may be connected to a first drain electrode 230D to thereby prevent a phenomenon in which a drain current rapidly increases due to accumulation of parasitic carriers in the first semiconductor layer 210 and a change in the threshold voltage due to such a phenomenon.

The light blocking layer 200 may include at least one of titanium (Ti), molybdenum (Mo), copper (Cu), aluminum (Al), silver (Ag), chromium (Cr), gold (Au), neodymium (Nd), and nickel (Ni) and may be formed as a single layer or multiple layers. However, the embodiments of the present disclosure are not limited thereto.

A first insulation layer 110 may be disposed on the light blocking layer 200.

The first insulation layer 110 may be formed of an insulating material such as silicon nitride (SiNx) or silicon oxide (SiOx). Alternatively, the first insulation layer 110 may be formed of an insulating inorganic material or organic material. However, the embodiments of the present disclosure are not limited thereto.

The first semiconductor layer 210 of the driving transistor DR Tr in the display area AA and a second semiconductor layer 400 of the first gate driving transistor GT1 in the non-display area NA may be disposed on the first insulation layer 110. The first semiconductor layer 210 may overlap the light blocking layer 200.

The first semiconductor layer 210 and the second semiconductor layer 400 may be formed of a metal oxide semiconductor, for example, indium gallium zinc oxide (IGZO), indium zinc oxide (IZO), indium gallium tin oxide (IGTO), or indium gallium oxide (IGO), but is not limited thereto.

The metal oxide semiconductor may have improved conductivity characteristics by a doping process of implanting impurities and may include a channel region in which a channel through which electrons or holes move is formed and source and drain regions that are conductive regions on both sides of the channel region. Source and drain electrodes may be connected to the source and drain regions, respectively.

A first gate insulation layer 120 may be disposed on the first semiconductor layer 210 and the second semiconductor layer 400. The first gate insulation layer 120 may be formed of an insulating material such as silicon nitride (SiNx) or silicon oxide (SiOx). Alternatively, the first gate insulation layer 120 may be formed of an insulating inorganic material or organic material. However, the embodiments of the present disclosure are not limited thereto.

A first gate electrode 220 and a second gate electrode 410 may be disposed on the first gate insulation layer 120 and may overlap the first semiconductor layer 210 and the second semiconductor layer 400, respectively. The first gate electrode 220 and the second gate electrode 410 may be formed of one or more of silver (Ag), molybdenum (Mo), copper (Cu), titanium (Ti), aluminum (Al), chromium (Cr), gold (Au), nickel (Ni), neodymium (Nd), and tungsten (W), and the embodiments of the present disclosure are not limited thereto.

A first capacitor electrode Cst1 of a capacitor PXL Cst included in the sub-pixel, a first metal layer 300 overlapping the switching transistor SW Tr of the sub-pixel, and a second metal layer 500 overlapping the second gate driving transistor GT2 may be formed and disposed through the same process as the first gate electrode 220 and the second gate electrode 410.

The first metal layer 300 and the second metal layer 500 may be served as lower gate electrodes of the switching transistor SW Tr and the second gate driving transistor GT2, respectively, or may be used as light blocking layers to block light reflected toward a third semiconductor layer 310 of the switching transistor SW Tr and a fourth semiconductor layer 510 of the second gate driving transistor GT2, respectively. However, the embodiments of the present disclosure are not limited thereto.

A second insulation layer 130 may be disposed on the first gate electrode 220, the second gate electrode 410, the first metal layer 300, the second metal layer 500, and the first capacitor electrode Cst1.

The second insulation layer 130 may be formed of an insulating material such as silicon nitride (SiNx) or silicon oxide (SiOx). Alternatively, the second insulation layer 130 may be formed of an insulating inorganic material or organic material. However, the embodiments of the present disclosure are not limited thereto.

A second capacitor electrode Cst2 of the sub-pixel capacitor PXL Cst may be disposed on the second insulation layer 130. The second capacitor electrode Cst2 may overlap the first capacitor electrode Cst1 and may be formed of the same material as the first capacitor electrode Cst1.

A third insulation layer 140 may be disposed on the second capacitor electrode Cst2.

The third insulation layer 140 may be formed of an insulating material such as silicon nitride (SiNx) or silicon oxide (SiOx). Alternatively, the third insulation layer 140 may be formed of an insulating organic material. However, the embodiments of the present disclosure are not limited thereto.

The third semiconductor layer 310 of the switching transistor SW Tr of the display area AA and the fourth semiconductor layer 510 of the second gate driving transistor GT2 of the non-display area NA may be disposed on the third insulation layer 140.

The third semiconductor layer 310 and the fourth semiconductor layer 510 may be formed of low temperature polycrystalline silicon (LTPS).

A second gate insulation layer 150 may be disposed on the third semiconductor layer 310 and the fourth semiconductor layer 510. The second gate insulation layer 150 may be interposed between the third semiconductor layer 310 and a third gate electrode 320 and between the fourth semiconductor layer 510 and a fourth gate electrode 520 to insulate the third semiconductor layer 310 and the fourth semiconductor layer 510 from third gate electrode 320 and the fourth gate electrode 520, respectively.

A channel region and source/drain regions may be formed in the LTPS semiconductor layer through doping, and the source/drain regions may be connected to source/drain electrodes.

The second gate insulation layer 150 may be formed of an insulating inorganic material such as silicon nitride (SiNx) or silicon oxide (SiOx). Alternatively, the second gate insulation layer 150 may be formed of an insulating organic material. However, the embodiments of the present disclosure are not limited thereto.

The third gate electrode 320 and the fourth gate electrode 520 may overlap the third semiconductor layer 310 and the fourth semiconductor layer 510, respectively.

The third gate electrode 320 and the fourth gate electrode 520 may be formed of one or more of silver (Ag), molybdenum (Mo), copper (Cu), titanium (Ti), aluminum (Al), chromium (Cr), gold (Au), nickel (Ni), neodymium (Nd), tungsten (W), and an alloy thereof and may be formed as a single layer or multiple layers. However, the embodiments of the present disclosure are not limited thereto.

A fourth insulation layer 160 may be disposed on the third gate electrode 320 and the fourth gate electrode 520.

The fourth insulation layer 160 may be formed of an insulating inorganic material such as silicon nitride (SiNx) or silicon oxide (SiOx) or may be formed of one or more organic insulating materials such as benzocyclobutene (BCB), acrylic resin, epoxy resin, phenolic resin, polyamide resin, or polyimide resin. However, the embodiments of the present disclosure are not limited thereto.

A first source electrode 230S and a first drain electrode 230D connected to the first semiconductor layer 210, a second source electrode 420S and a second drain electrode 420D connected to the second semiconductor layer 400, a third source electrode 330S and a third drain electrode 330D connected to the third semiconductor layer 310, and a fourth source electrode 530S and a fourth drain electrode 530D connected to the fourth semiconductor layer 510 may be disposed on the fourth insulation layer 160.

The first source electrode 230S and the first drain electrode 230D may be connected to the first semiconductor layer 210 through contact holes formed in the first gate insulation layer 120, the second insulation layer 130, the third insulation layer 140, the second gate insulation layer 150, and the fourth insulation layer 160. The second source electrode 420S and the second drain electrode 420D may be connected to the second semiconductor layer 400 through contact holes formed in the first gate insulation layer 120, the second insulation layer 130, the third insulation layer 140, the second gate insulation layer 150, and the fourth insulation layer 160.

The third source electrode 330S and the third drain electrode 330D may be connected to the third semiconductor layer 310 through contact holes formed in the second gate insulation layer 150 and the fourth insulation layer 160. The fourth source electrode 530S and the second drain electrode 530D may be connected to the fourth semiconductor layer 510 through contact holes formed in the second gate insulation layer 150 and the fourth insulation layer 160.

The first source electrode 230S, the first drain electrode 230D, the second source electrode 420S, the second drain electrode 420D, the third source electrode 330S, the third drain electrode 330D, the fourth source electrode 530S, and the fourth drain electrode 530D may be formed through the same process and may be formed of one or more of silver (Ag), molybdenum (Mo), copper (Cu), titanium (Ti), aluminum (Al), chromium (Cr), gold (Au), nickel (Ni), neodymium (Nd), and tungsten (W).

A first line 630 may be formed and disposed in the non-display area NA through the same process as the first source electrode 230S, the first drain electrode 230D, the second source electrode 420S, the second drain electrode 420D, the third source electrode 330S, the third drain electrode 330D, the fourth source electrode 530S, and the fourth drain electrode 530D.

The first line 630 may be a line for transmitting a voltage applied to a cathode electrode 620.

A first planarization layer 170 may be disposed on the first source electrode 230S, the first drain electrode 230D, the second source electrode 420S, the second drain electrode 420D, the third source electrode 330S, the third drain electrode 330D, the fourth source electrode 530S, and the fourth drain electrode 530D.

The first planarization layer 170 may be formed of an organic insulating material such as polyacrylate or polyimide and can reduce steps due to the lines and contact holes formed thereunder.

A connection electrode 240 for connecting the first drain electrode 230D and an anode electrode 600 may be disposed on the first planarization layer 170.

The connection electrode 240 may be electrically connected to the first drain electrode 230D through a hole formed in the first planarization layer 170.

The connection electrode 240 may include one or more of titanium (Ti), molybdenum (Mo), copper (Cu), aluminum (Al), silver (Ag), chromium (Cr), gold (Au), neodymium (Nd), and nickel (Ni) or may be formed of an alloy thereof, and the embodiments of the present disclosure are not limited thereto.

A second planarization layer 180 may be disposed on the connection electrode 240. The second planarization layer 180 may be formed of an organic insulating material such as polyacrylate or polyimide, and the embodiments of the present disclosure are not limited thereto.

The anode electrode 600 may be disposed on the second planarization layer 180. The anode electrode 600 may be electrically connected to the connection electrode 240 through a hole formed in the second planarization layer 180.

A second line 640 may be formed in the non-display area NA through the same process as the anode electrode 600. The second line 640 may overlap parts of the first gate driving transistor GT1 and the second gate driving transistor GT2 and may be connected to the first line 630 disposed in the non-display area NA to apply a voltage to the cathode electrode 620.

The anode electrode 600 and the second line 640 may be formed of one or more of silver (Ag), aluminum (Al), gold (Au), molybdenum (Mo), tungsten (W), chromium (Cr), palladium (Pd), indium tin oxide (ITO), indium zinc oxide (IZO), and an alloy thereof, and the embodiments of the present disclosure are not limited thereto.

A bank 190 may be disposed on the anode electrode 600, the second line 640, and the second planarization layer 180.

The bank 190 may partition the plurality of sub-pixels, minimize or reduce a light blurring phenomenon, and prevent color mixing occurring at various viewing angles.

The bank 190 may expose the anode electrode 600 corresponding to an emission area and overlap end portions of the anode electrode 600.

The bank 190 may be formed of an inorganic insulating material such as silicon nitride (SiNx) or silicon oxide (SiOx) or formed of one or more organic materials of benzocyclobutene (BCB), acryl resin, epoxy resin, phenolic resin, polyamide resin, or polyimide resin. However, the embodiments of the present disclosure are not limited thereto.

A spacer 191 may be further disposed on the bank 190. The spacer 191 may support a gap between the substrate 100 where a light emitting element layer 610 is formed and an upper substrate, thereby minimizing damage to elements inside the display panel when an external physical impact is applied. The spacer 191 may be formed of the same material as the bank 190, and may be formed simultaneously with the bank 190. However, the embodiments of the present disclosure are not limited thereto.

The light emitting element layer 610 may be disposed on an opening of the bank 190 exposing the anode electrode 600. The light emitting element layer 610 may include one or more organic light emitting layers among a red light emitting layer, a green light emitting layer, a blue light emitting layer, and a white light emitting layer to emit light of a specific color. In addition, the light emitting element layer 610 may further include a hole injection layer, a hole transport layer, an electron transport layer, and an electron injection layer in addition to the organic light emitting layer, and the embodiments of the present disclosure are not limited thereto.

The hole injection layer, the hole transport layer, the electron transport layer, and the electron injection layer may be disposed for each sub-pixel with different thicknesses and materials or may be disposed in common over a substantially entire surface of the substrate 100.

When the light emitting element layer 610 includes a white organic light emitting layer, the light emitting element layer 610 may be disposed on the opening of the bank 190 and the substantially entire surface of the substrate 100.

A color filter may be disposed on the light emitting element layer 610 to convert light emitted from the white organic light emitting layer into light of a different color.

The cathode electrode 620 may be disposed on the light emitting element layer 610. The cathode electrode 620 may supply electrons to the light emitting element layer 610 and may be formed of a conductive material having relatively low work function.

When the display apparatus 10 is a top emission type, the cathode electrode 620 may be formed of a transparent conductive material through which light is transmitted. For example, the cathode electrode 620 may be formed of at least one of indium tin oxide (ITO) and indium zinc oxide (IZO), but is not limited thereto.

Alternatively, the cathode electrode 620 may be formed of a translucent conductive material through which light is transmitted. For example, the cathode electrode 620 may be formed of at least one of alloys such as LiF/Al, CsF/Al, Mg:Ag, Ca/Ag, Ca:Ag, LiF/Mg:Ag, LiF/Ca/Ag, and LiF/Ca:Ag, but is not limited thereto.

When the display apparatus 10 is a bottom emission type, the cathode electrode 620 may be a reflective electrode that reflects light and may be formed of an opaque conductive material. For example, the cathode electrode 620 may be formed of at least one of silver (Ag), aluminum (Al), gold (Au), molybdenum (Mo), tungsten (W), chromium (Cr), and an alloy thereof.

An end part including a driving circuit portion and a second dam portion in which a plurality of dams are located may be disposed in the non-display area NA of the display apparatus 10.

The end part of the non-display area NA may be an area in which the cathode electrode 620 is electrically connected to the line for applying a voltage to the cathode electrode and in which the display apparatus 10 is sealed using a plurality of dams.

The first insulation layer 110, the first gate insulation layer 120, the second insulation layer 130, and the third insulation layer 140 on the substrate 100 may be extended into and disposed in the end part.

Signal lines may be disposed in the end part so that the power supply voltage and touch signals applied from the FPCB of the display apparatus may be connected to the display panel through the signal lines.

The first line 630 may be disposed on the fourth insulation layer 160, may be in contact with side surfaces of the fourth insulation layer 160 and the second gate insulation layer 150, and may be extended and disposed between the first dam DM1 and the third insulation layer 140 of the non-display area NA.

The first dam DM1 may be formed and stacked using the same materials and processes as the first planarization layer 170 and the bank 190.

The second dam DM2 may be formed and stacked using the same materials and processes as the first planarization layer 170, the second planarization layer 180, the bank 190, and the spacer 191.

The first dam DM1 and the second dam DM2 may have a first height and a second height, respectively and may surround the display area AA.

The second height may be higher than the first height. Even if a second encapsulation layer 720 exceeds the first dam DM1 of the second dam portion, the second encapsulation layer 720 may not be formed outside the second dam portion due to the second dam DM2.

A first encapsulation layer 710 and a third encapsulation layer 730 may be disposed to extend beyond the second dam DM2 to the outer portion.

The second line 640 may be disposed between the first planarization layer 170 and the bank 190 of the first dam DM1 and between the second planarization layer 180 and the bank 190 of the second dam DM2.

The cathode electrode 620 may extend to a region between the first dam DM1 and the second dam DM2 and may be electrically connected to the first line 630 and the second line 640.

An encapsulation layer 700 may be disposed on the cathode electrode 620 of the display area AA and on the cathode electrode 620 and the second dam DM2 of the non-display area NA.

The encapsulation layer 700 may protect the display apparatus 10 from external moisture, oxygen, or foreign substances or particles. For example, the encapsulation layer 700 may prevent penetration of oxygen and moisture from the outside in order to prevent oxidation of the light emitting material and the electrode material.

The encapsulation layer 700 may be formed of a transparent material so that light emitted from the light emitting element layer 610 is transmitted.

The encapsulation layer 700 may include the first encapsulation layer 710, the second encapsulation layer 720, and the third encapsulation layer 730 that block penetration of moisture or oxygen, and the embodiments of the present disclosure are not limited thereto. The first encapsulation layer 710, the second encapsulation layer 720, and the third encapsulation layer 730 may have a sequentially stacked structure, and the embodiments of the present disclosure are not limited thereto.

The first encapsulation layer 710 and the third encapsulation layer 730 may be formed of at least one inorganic material of silicon nitride (SiNx), silicon oxide (SiOx), or aluminum oxide (AlyOz), and the embodiments of the present disclosure are not limited thereto.

The second encapsulation layer 720 may cover foreign substances or particles that may occur during the manufacturing process. In addition, the second encapsulation layer 720 may flatten a surface of the first encapsulation layer 710.

The second encapsulation layer 720 may be formed of an organic material, for example, a polymer such as silicon oxy carbon (SiOCz), epoxy, polyimide, polyethylene, or acrylate. However, the embodiments of the present disclosure are not limited thereto.

A touch buffer layer 800 may be disposed on the third encapsulation layer 730. The touch buffer layer 800 may be disposed on the substantially entire surface of the display area AA and the non-display area NA, and may extend to a pad portion. The touch buffer layer 800 may be referred to as a first insulating layer, and the term is not limited thereto.

The touch buffer layer 800 may be formed of at least one inorganic material of silicon nitride (SiNx), silicon oxide (SiOx), or aluminum oxide (AlyOz), and the embodiments of the present disclosure are not limited thereto.

A first touch electrode 810 may be disposed on the touch buffer layer 800.

Touch driving may be performed by a plurality of sensing electrodes and a plurality of driving electrodes disposed in the display area AA. The sensing electrodes may include a plurality of sub-sensing electrodes that extend along a first direction and are spaced apart from each other along a second direction. The plurality of sub-sensing electrodes may be continuously formed without being disconnected in the first direction.

The plurality of driving electrodes may include a plurality of sub-driving electrodes that extend along the second direction and are spaced apart from each other along the first direction. The plurality of sub-driving electrodes may be electrically connected to each other in the second direction.

When the plurality of sub-sensing electrodes and the plurality of sub-driving electrodes are formed on the same layer, the plurality of sub-driving electrodes may be electrically connected to each other by a bridge pattern.

The plurality of sub-sensing electrodes and the plurality of sub-driving electrodes may have a metal mesh structure.

Alternatively, the plurality of sub-sensing electrodes may be electrically connected to each other by a bridge pattern, and the plurality of sub-driving electrodes Tx may be continuously formed without being disconnected and may be electrically connected.

The first touch electrode 810 may electrically connect the plurality of sub-sensing electrodes or the plurality of sub-driving electrodes to each other.

The first touch electrode 810 may be formed of a metal material such as molybdenum (Mo), silver (Ag), titanium (Ti), copper (Cu), aluminum (Al), titanium/aluminum/titanium (Ti/Al/Ti), or molybdenum/aluminum/molybdenum (Mo/Al/Mo) and may have a single layer or multiple layers. However, the embodiments of the present disclosure are not limited thereto.

A touch insulation layer 820 may be disposed on the first touch electrode 810. The touch insulation layer 820 may be disposed on the substantially entire surface of the display area AA and the non-display area NA, and may extend to the pad portion. The touch insulation layer 820 may be referred to as a second insulating layer, and the term is not limited thereto.

The touch insulation layer 820 may be formed of at least one inorganic material of silicon nitride (SiNx), silicon oxide (SiOx), or aluminum oxide (AlyOz), and the embodiments of the present disclosure are not limited thereto.

A second touch electrode 830 may be disposed on the touch insulation layer 820. The second touch electrode 830 may be the plurality of sub-sensing electrodes or the plurality of sub-driving electrodes for the touch driving.

A touch line 840 for transmitting a touch driving signal may be disposed in the non-display area NA through the same process of forming the second touch electrode 830.

The touch line 840 may overlap the first gate driving transistor GT1 or the second gate driving transistor GT2 and may be extend to the pad portion.

The second touch electrode 830 and the touch line 840 may be formed of a metal material such as molybdenum (Mo), silver (Ag), titanium (Ti), copper (Cu), aluminum (Al), titanium/aluminum/titanium (Ti/Al/Ti), or molybdenum/aluminum/molybdenum (Mo/Al/Mo) and may have a single layer or multiple layers. However, the embodiments of the present disclosure are not limited thereto.

A third planarization layer 850 may be disposed on the second touch electrode 830 and the touch line 840.

The third planarization layer 850 may cover and flatten the second touch electrode 830, the touch line 840, and the touch insulation layer 820. The third planarization layer 850 may be formed of one or more organic insulating materials such as benzocyclobutene, acrylic resin, epoxy resin, phenolic resin, polyamide resin, or polyimide resin. However, the embodiments of the present disclosure are not limited thereto.

An adhesive layer 900 and a cover window 910 may be disposed on the third planarization layer 850.

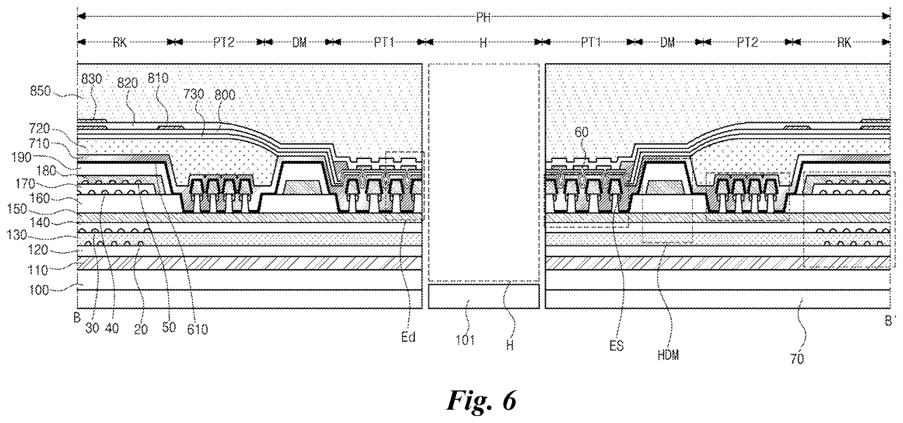

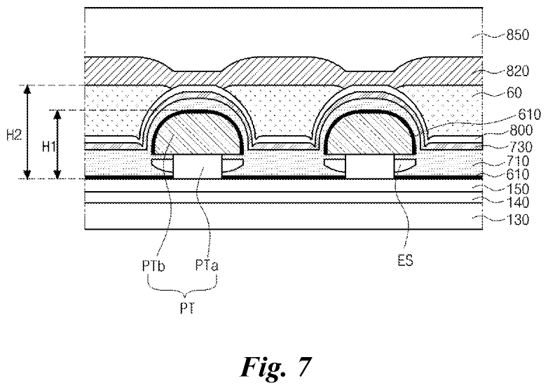

The first area PH shown in FIG. 4 will be described in detail with reference to FIG. 6 and FIG. 7.

The first area PH may include the hole region H for disposing a camera and the first pattern portion PT1, the first dam portion DM, the second pattern portion PT2, and the routing wiring region RK surrounding the hole region H.

The hole region H may be disposed in the center of the first area PH and may be formed to physically penetrate from the substrate 100 to the third planarization layer 850. The hole region H may be provided with a camera, a sensor, and a light source, and light may be easily transmitted by the hole region H over the camera or the sensor.

In the routing wiring region RK, routing lines for electrically connecting the sub-pixels of the display area AA at both sides of the first area PH to each other may be disposed.

A first routing line 20 may be formed on the first gate insulation layer 120 extending into the first area PH through the same process of forming the first gate electrode 220, the second gate electrode 410, the first metal layer 300, the second metal layer 500, and the first capacitor electrode Cst1, and the embodiments of the present disclosure are not limited thereto.

A second routing line 30 may be formed on the second insulation layer 130 extending into the first area PH through the same process of forming the second capacitor electrode Cst2, and the embodiments of the present disclosure are not limited thereto.

A third routing line 40 may be formed on the fourth insulation layer 160 extending into the first area PH through the same process of forming the first source electrode 230S, the first drain electrode 230D, the second source electrode 420S, the second drain electrode 420D, the third source electrode 330S, the third drain electrode 330D, the fourth source electrode 530S, and the fourth drain electrode 530D, and the embodiments of the present disclosure are not limited thereto.

A fourth routing line 50 may be formed on the first planarization layer 170 extending into the first area PH through the same process of forming the connection electrode 240, and the embodiments of the present disclosure are not limited thereto.

In the routing wiring region RK, the first touch electrode 810 and the second touch electrode 830 may be formed as lines for routing to transmit the touch driving signals to the display area AA.

The gate lines of the sub-pixels of the display area AA may be connected to the first routing line 20 and the second routing line 30, thereby being also electrically connected in the first area PH. The data lines of the sub-pixels of the display area AA may be connected to the third routing line 40 and the fourth routing line 50, thereby being also electrically connected in the first area PH.

The first pattern portion PT1 and the second pattern PT2 may be disposed to surround the hole region H. Each of the first pattern portion PT1 and the second pattern portion PT2 may include a plurality of patterns PT, and each of the plurality of patterns PT may include a lower pattern PTa and an upper pattern PTb. The lower pattern PTa may be simultaneously formed of the same material as the fourth insulation layer 160, and the upper pattern PTb may be simultaneously formed of the same material as the second planarization layer 180. However, the material and number of layers of the plurality of patterns PT are not limited thereto.

The plurality of patterns PT may be arranged to be spaced apart from each other by a predetermined or selected distance.

The plurality of patterns PT may prevent moisture from penetrating into the display area AA through the light emitting element layer 610, which is vulnerable to moisture penetration.

A lower surface of the upper pattern PTb disposed on the lower pattern PTa may have a wider width than an upper surface of the lower pattern PTa.

The light emitting element layer 610 may not be formed on the side surface of the lower pattern PTa due to a space between the lower surface of the upper pattern PTb and the side surface of the lower pattern PTa, so that the light emitting element layer 610 disposed on the upper and side surfaces of the upper pattern PTb may be separated from the light emitting element layer 610 disposed on the second gate insulation layer 150.

In addition, the first encapsulation layer 710 disposed in the routing wiring region RK, the first pattern portion PT1, the first dam portion DM, and the second pattern portion PT2 of the first area PH may be formed on the upper and side surfaces of the upper pattern PTb and on a part of the lower surface of the upper pattern PTb and may not be formed on a part of the side surface of the lower pattern PTa, so that an empty space ES may be formed.

A hole dam HDM may be disposed in the first dam portion DM between the first pattern portion PT1 and the second pattern portion PT2.

The hole dam HDM may prevent the second encapsulation layer 720 from overflowing into the hole region H. One or more hole dams HDM may be consecutively disposed or may be disposed in the first pattern portion PT1 and the second pattern portion PT2.

The hole dam HDM may be formed by stacking patterns formed of the same material in the same process as the fourth insulation layer 160, the second planarization layer 180, and the bank 190, and the embodiments of the present disclosure are not limited thereto.

Due to the hold dam HDM, the second encapsulation layer 720 may be disposed only in the second pattern portion PT2 and on the part of the hold dam HDM.

The third encapsulation layer 730 may be disposed in the routing wiring region RK, the first pattern portion PT1, the dam portion DM, and the second pattern portion PT2 of the first area PH and may be close to or in contact with the first encapsulation layer 710 on the upper and side surfaces of the plurality of patterns PT of the first pattern portion PT1.

The touch buffer layer 800 may extend and be disposed on the third encapsulation layer 730 in the routing wiring region RK, the first pattern portion PT1, the dam portion DM, and the second pattern portion PT2 of the first area PH.

The touch insulation layer 820 may extend and be disposed in the routing wiring region RK, the first pattern portion PT1, the dam portion DM, and the second pattern portion PT2 of the first area PH and may be in contact with the upper surface of the touch buffer layer 800 in the second pattern portion PT2 and on the hole dam HDM.

A protective layer 60 may be disposed between the touch buffer layer 800 and the touch insulation layer 820 in the region between the plurality of patterns PT of the first pattern portion PT1, so that the touch buffer layer 800 and the touch insulation layer 820 may be spaced apart from each other.

An end of the protective layer 60 may partially overlap the plurality of patterns PT between the plurality of patterns PT of the first pattern portion PT1.

The protective layer 60 may be formed of at least one organic insulating material such as acrylic resin, epoxy region, phenolic resin, polyamide resin, or polyimide resin, and the embodiments of the present disclosure are not limited thereto.

Moisture injected through the hole region H may penetrate into the empty space ES formed at the pattern PT of the first pattern portion PT1 through the third planarization layer 850 formed of an organic material and move into the display area AA, so that the quality of the display panel may deteriorate.

The protective layer 60 may be disposed between the plurality of patterns PT, and the touch buffer layer 800 and the touch insulation layer 820 may be in contact with each other.

Although the protective layer 60 is formed of an organic material, the protective layer 60 may be disconnected by the touch buffer layer 800 and the touch insulation layer 820 on the plurality of patterns PT, thereby preventing moisture from moving through the protective layer 60.

In addition, by forming the protective layer 60, the distance from the empty space ES and the seam to the third planarization layer 850 may increase, so that moisture in the third planarization layer 850 may not be transmitted to the empty space ES.

A first height H1 from the lower surface of the lower pattern PTa to the upper surface of upper pattern PTb of the plurality of patterns PT of the first pattern portion PT1 may be different from a second height H2 from the lower surface of the lower pattern PTa to the upper surface of the protective layer 60. The second height H2 may be higher than the first height H1.

The side surface of the first pattern portion PT1, that is, the side surfaces of the insulation layers such as the pattern PT, the first encapsulation layer 710, the third encapsulation layer 730, the touch buffer layer 800, and the touch insulation layer 820, which are disposed at the end part of the first pattern portion PT1 adjacent to the hole region H, may be exposed in the hole region H.

A support plate 70 of the display apparatus 10 may be disposed under the substrate 100. A hole may be formed in the hole region H so that the support plate 70 may correspond to the hole region H, and an optical portion 101 including a camera, a sensor, and a light source may be disposed in the hole.

A display apparatus according to embodiments of the present disclosure may be described as follows.

A display apparatus according to an embodiment of the present disclosure comprises a display area, a first area disposed in the display area and comprising a hole region and a first pattern portion surrounding the hole region, a plurality of first patterns disposed in the first pattern portion, and a first insulating layer and a second insulating layer disposed on the plurality of first patterns, wherein the first insulating layer and the second insulating layer are spaced apart from each other between the plurality of first patterns, and wherein the first insulating layer and the second insulating layer are in contact with each other on an upper surface of each of the plurality of first patterns.

According to some embodiments of the present disclosure, the first area may further comprise a second pattern portion surrounding the first pattern portion and a plurality of second patterns disposed in the second pattern portion, wherein an encapsulation layer may be disposed on the plurality of second patterns without extending to the first pattern portion, and wherein the first insulating layer and the second insulating layer may be disposed on the encapsulation layer in the second pattern portion.

According to some embodiments of the present disclosure, the first insulating layer and the second insulating layer may be spaced apart from each other between the plurality of first patterns by a protective layer.

According to some embodiments of the present disclosure, an upper surface of each of the plurality of first patterns may be lower than an upper surface of the protective layer.

According to some embodiments of the present disclosure, the protective layer may partially overlap the plurality of first patterns.

According to some embodiments of the present disclosure, the first area may further comprise a first dam portion between the first pattern portion and the second pattern portion, and a hole dam disposed in the first dam portion.

According to some embodiments of the present disclosure, an upper surface of the hole dam may be higher than an upper surface of each of the plurality of second patterns.

According to some embodiments of the present disclosure, each of the plurality of first patterns may comprise a lower pattern and an upper pattern disposed on the lower pattern, and an lower surface of the upper pattern may be wider than an upper surface of the lower pattern.

According to some embodiments of the present disclosure, an empty space may be formed between a side surface of the lower pattern and the lower surface of the upper pattern.

According to some embodiments of the present disclosure, the display apparatus may further comprise an anode electrode, a light emitting layer, and a cathode electrode disposed in the display area.

According to some embodiments of the present disclosure, the encapsulation layer may be disposed on the cathode electrode.

According to some embodiments of the present disclosure, the display apparatus further comprise a first touch electrode disposed on the first insulating layer and a second touch electrode disposed on the second insulating layer.

According to some embodiments of the present disclosure, side surfaces of the first insulating layer and the second insulating layer may be exposed in the hole region.

According to some embodiments of the present disclosure, the display apparatus may further comprise a camera, a sensor or a light source disposed in the hole region.

According to some embodiments of the present disclosure, the display apparatus may further comprise a non-display area and a second dam portion disposed in the non-display area.

A display apparatus according to another embodiment of the present disclosure comprises a display area, a first area and a plurality of pixels disposed in the display area, an anode electrode, a light emitting layer, and a cathode electrode disposed in each of the plurality of pixels, an encapsulation layer disposed on the cathode electrode, a first insulating layer disposed on the encapsulation layer, a first touch electrode disposed on the first insulating layer, a second insulating layer disposed on the first touch electrode, and a second touch electrode disposed on the second insulating layer, the first area may comprise a first pattern portion, a second pattern portion, and a first dam portion between the first pattern portion and the second pattern portion, wherein the first insulating layer and the second insulating layer extend in the first pattern portion, the first dam portion, and the second pattern portion.

According to some another embodiments of the present disclosure, the first pattern portion may comprise a plurality of first patterns.

According to some another embodiments of the present disclosure, the first insulating layer and the second insulating layer may be in contact with each other on an upper surface of each of the plurality of first patterns.

According to some another embodiments of the present disclosure, the first insulating layer and the second insulating layer may be spaced apart from each other between the plurality of first patterns.

According to some another embodiments of the present disclosure, the first insulating layer and the second insulating layer may be spaced apart from each other between the plurality of first patterns by a protective layer.

According to some another embodiments of the present disclosure, an upper surface of each of the plurality of first patterns may be lower than an upper surface of the protective layer.

According to some another embodiments of the present disclosure, the protective layer partially overlaps the plurality of first patterns.

According to some another embodiments of the present disclosure, the second pattern portion may comprise a plurality of second patterns.

According to some another embodiments of the present disclosure, the encapsulation layer may be disposed on the plurality of second patterns without extending to the first pattern portion.

According to some another embodiments of the present disclosure, the first insulating layer and the second insulating layer may be in contact with each other in the second pattern portion.

According to some another embodiments of the present disclosure, the first area may further comprise a hole region adjacent to the first pattern portion, and a camera, a sensor or a light source may be disposed in the hole region.

According to some another embodiments of the present disclosure, side surfaces of the first insulating layer and the second insulating layer may be exposed in the hole region.

According to some another embodiments of the present disclosure, the display apparatus may further comprise a non-display area and a second dam portion disposed in the non-display area.

Although the embodiments of the present disclosure have been described in more detail with reference to the accompanying drawings, the present disclosure is not necessarily limited to these embodiments, and may be variously modified and implemented without departing from the technical spirit of the present disclosure. Accordingly, the embodiments disclosed in the present disclosure are not intended to limit the technical spirit of the present disclosure, but to explain, and the scope of the technical spirit of the present disclosure is not limited by these embodiments. Therefore, it should be understood that the embodiments described above are illustrative in all respects and not restrictive. The protection scope of the present disclosure should be interpreted by the claims, and all technical ideas within the equivalent range should be construed as being included in the scope of rights of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a display area;
a first area disposed in the display area, the first area including a hole region and a first pattern portion adjacent the hole region;
a plurality of first patterns disposed in the first pattern portion; and
a first insulating layer and a second insulating layer disposed on the plurality of first patterns,
wherein the first insulating layer and the second insulating layer are spaced apart from each other between the plurality of first patterns, and
wherein the first insulating layer and the second insulating layer are in contact with each other on an upper surface of each of the plurality of first patterns.

2. The display apparatus of claim 1, wherein the first area further comprises a second pattern portion adjacent the first pattern portion, and a plurality of second patterns disposed in the second pattern portion,
wherein an encapsulation layer is disposed on the plurality of second patterns without extending to the first pattern portion, and
wherein the first insulating layer and the second insulating layer are disposed on the encapsulation layer in the second pattern portion.

3. The display apparatus of claim 1, wherein the first insulating layer and the second insulating layer are spaced apart from each other between the plurality of first patterns by a protective layer.

4. The display apparatus of claim 3, wherein an upper surface of each of the plurality of first patterns is lower than an upper surface of the protective layer.

5. The display apparatus of claim 3, wherein the protective layer partially overlaps the plurality of first patterns.

6. The display apparatus of claim 2, wherein the first area further comprises a first dam portion between the first pattern portion and the second pattern portion, and a hole dam disposed in the first dam portion.

7. The display apparatus of claim 6, wherein an upper surface of the hole dam is higher than an upper surface of each of the plurality of second patterns.

8. The display apparatus of claim 1, wherein each of the plurality of first patterns comprises a lower pattern and an upper pattern disposed on the lower pattern,
wherein a lower surface of the upper pattern is wider than an upper surface of the lower pattern.

9. The display apparatus of claim 8, wherein an empty space is formed between a side surface of the lower pattern and the lower surface of the upper pattern.

10. The display apparatus of claim 2, further comprising an anode electrode, a light emitting layer, and a cathode electrode disposed in the display area.

11. The display apparatus of claim 10, wherein the encapsulation layer is disposed on the cathode electrode.

12. The display apparatus of claim 1, further comprising a first touch electrode disposed on the first insulating layer and a second touch electrode disposed on the second insulating layer.

13. The display apparatus of claim 1, wherein side surfaces of the first insulating layer and the second insulating layer are exposed in the hole region.

14. The display apparatus of claim 1, further comprising a camera, a sensor, or a light source disposed in the hole region.

15. The display apparatus of claim 6, further comprising a non-display area and a second dam portion disposed in the non-display area.

16. A display apparatus, comprising:
a display area;
a first area and a plurality of pixels disposed in the display area;
an anode electrode, a light emitting layer, and a cathode electrode disposed in each of the plurality of pixels;
an encapsulation layer disposed on the cathode electrode;
a first insulating layer disposed on the encapsulation layer;
a first touch electrode disposed on the first insulating layer;
a second insulating layer disposed on the first touch electrode; and
a second touch electrode disposed on the second insulating layer,
wherein the first area comprises a first pattern portion, a second pattern portion, and a first dam portion between the first pattern portion and the second pattern portion,
wherein the first insulating layer and the second insulating layer extend in the first pattern portion, the first dam portion, and the second pattern portion.

17. The display apparatus of claim 16, wherein the first pattern portion comprises a plurality of first patterns.

18. The display apparatus of claim 17, wherein the first insulating layer and the second insulating layer are in contact with each other on an upper surface of each of the plurality of first patterns.

19. The display apparatus of claim 17, wherein the first insulating layer and the second insulating layer are spaced apart from each other between the plurality of first patterns.

20. The display apparatus of claim 19, wherein the first insulating layer and the second insulating layer are spaced apart from each other between the plurality of first patterns by a protective layer.

21. The display apparatus of claim 20, wherein an upper surface of each of the plurality of first patterns is lower than an upper surface of the protective layer.

22. The display apparatus of claim 20, wherein the protective layer partially overlaps the plurality of first patterns.

23. The display apparatus of claim 16, wherein the second pattern portion comprises a plurality of second patterns.

24. The display apparatus of claim 23, wherein the encapsulation layer is disposed on the plurality of second patterns without extending to the first pattern portion.

25. The display apparatus of claim 24, wherein the first insulating layer and the second insulating layer are in contact with each other in the second pattern portion.

26. The display apparatus of claim 16, wherein the first area further comprises a hole region adjacent to the first pattern portion,
wherein a camera, a sensor or a light source is disposed in the hole region.

27. The display apparatus of claim 26, wherein side surfaces of the first insulating layer and the second insulating layer are exposed in the hole region.

28. The display apparatus of claim 16, further comprising a non-display area and a second dam portion disposed in the non-display area.
